(19) United States
(12) Patent Application Publication
(10) Pub. No.: US 2017/0161847 A1
(43) Pub. Date: Jun. 8, 2017

(54) POWER MANAGEMENT METHOD AND POWER MANAGEMENT DEVICE FOR A RESIDENTIAL COMPLEX COMPRISING ONE OR MORE RESIDENTIAL UNITS OR FOR AN URBAN DISTRICT

(71) Applicant: Evohaus GmbH, Karlsruhe (DE)

(72) Inventors: Heinze Hanen, Karlsruhe (DE); Frank Diedrich, Karlsruhe (DE); Valentin Bertsch, Karlsruhe (DE); Hannes Schwarz, Karlsruhe (DE)

(21) Appl. No.: 15/324,324

(22) PCT Filed: Jul. 8, 2015
(86) PCT No.: PCT/EP2015/065610

§ 371 Date: Jan. 6, 2017

(30) Foreign Application Priority Data
Jul. 8, 2014 (DE) 10 2014 010 071.5

(51) Int. Cl. G06Q 50/06; G01R 21/00; G06Q 10/06; G01R 21/133; H02J 3/14; H02J 3/34

(52) U.S. Cl. CPC G06Q 50/06; H02J 3/14; H02J 3/34; G06Q 10/06; G01R 21/1331; G01R 21/001

(57) ABSTRACT

The present invention provides a power management method and a power management device for a residential complex comprising one or more residential units or for an urban district, comprising a shared connection via which self-supplied electricity from a time-variable generation capacity is supplied to the mains power network from a decentralised self-supplied-electricity generation apparatus, and via which mains electricity is supplied to the residential complex or the urban district from the mains power network. The method is configured such that the demand not covered by the decentralised self-supplied-electricity generation apparatus is determined according to the mains supply level 1−S of the electricity and the demand covered by the decentralised self-supplied-electricity generation apparatus is determined according to the self-supply level S of the electricity for the residential complex or urban district, time dependency of the electrical consumption of a residential unit is recorded, and electricity costs for the residential unit of the residential complex or of the urban district are determined by taking into account the determined time dependency of the mains supply level and the self-supply level, the recorded time dependency of the electricity consumption of the residential unit, and the relevant tariffs for mains electricity and self-supplied electricity.

### TECHNICAL FIELD

The present invention relates to a power management method and a power management device for a residential complex comprising one or more residential units or for an urban district, comprising a shared connection via which self-supplied electricity from a time-variable generation capacity is supplied to the mains power network from a decentralised self-supplied-electricity generation apparatus, and via which mains electricity is supplied to the residential complex or the urban district from the mains power network.

A system for managing electrical power in residential complexes or urban districts is described. The problem addressed by the invention is incentive-based optimisation of consumption while maintaining convenience. Within the meaning of this document, residential complexes or urban districts are residential complexes having spatially or legally separate residential units or groups of residential units which share facilities.

In particular, these are residential complexes or urban districts which are equipped with local, decentralised power generation units (e.g. a photovoltaic system) for producing electrical power, the residential complexes or urban districts in question not being completely self-sufficient in terms of their supply of electricity. They are therefore connected to the mains power network, in order for it to be possible to draw the proportion of their electrical demand that is not intended to be covered in a decentralised manner from the mains.

Urban districts may consist of a plurality of residential complexes that share facilities. The invention generally relates to residential complexes or urban districts, but in the following, for reasons of better readability, the invention is described for the specific case of a residential complex.

### DESCRIPTION OF THE PROBLEM

Convenience when using certain domestic electrical appliances is often not dependent on the specific time at which they are being operated. Instead, convenience is often solely dependent on the fact that a domestic appliance has completed a task by a particular set end time. Between the time at which the decision is made that a task needs to be completed and the time at which this task needs to be completed, there is in many cases a time interval that is greater than that the time that the domestic appliance requires to complete the task in terms of its operating time. In such situations, it is possible to vary the operating period of the appliance within the time frame specified by the user. It is therefore advantageous for the residents of the residential complex to set the operating time of electrical loads such that they operate at times having the lowest possible electricity tariff. A problem of this kind is known as load transfer. The problem is that of controlling electrical loads such that they perform the tasks expected of them and incur the lowest possible energy costs in the process.

In the case in question of a residential complex having an associated local, decentralised power generation unit and a connection to the mains power network, the power costs for the residents of the residential complex depend on the relevant supply status. In the extreme case that the entirety of the electrical demand of the residential complex can be covered by decentralised generation, no electricity is drawn from the mains network. In this case, the electricity costs arise solely from the operating costs of the local, decentralised power generation unit and any opportunity costs to be included. In the other extreme case in which decentralised generation cannot contribute to covering any of the demand, all the electrical power has to be drawn from the mains network. In this case, the electricity costs of the residential complex are determined exclusively in accordance with the electricity tariff of the energy supplier. Between these two extreme cases, there is a situation in which some of the electrical demand can be covered by decentralised generation in the form of self-consumption, and the rest has to be drawn from the mains. This results in a mixed tariff for the electricity costs for the residential complex, these costs falling between the electricity costs for the above-mentioned extreme cases. It is clear that different electricity costs arise at different times.

Furthermore, it may be that there is a variable price from the energy supplier for drawing power from the mains power network. Here, a time-variable kilowatt-hour rate is just as conceivable as a demand rate, which is oriented towards the services received per time interval. These aspects should then also be taken into account when calculating the mixed price.

It is therefore advantageous for the residents of the residential complex to set the operating time of electrical loads such that they operate at times having the lowest possible electricity costs. A problem of this kind is known as load transfer. The challenge is to set the operating time of electrical loads such that they incur the lowest possible energy costs while performing the tasks expected of them within the time frame predetermined by the user.

### PRIOR ART

Residential complexes are known in which houses are equipped with decentralised power generation units, such as photovoltaic systems or cogeneration systems, and are connected to an electrical network. It is also known that residential estates of this type are equipped with a control system, which first uses electricity that is self-generated in a decentralised manner on site in the residential estate for self-consumption, and then feeds excess power into the mains, e.g. from the document “Eigenversorgung mit Photovoltaik, dezentralen Speichern und intelligentem Energiemanagement” [Self-sufficient supply using photovoltaics, decentralised storage and intelligent power management] by SMA AGG [presentation by Dipl.-Wirt.-Ing. Andreas Umland, Director Business Opportunity Management at SMA AG at the ABGnova SophienHofAbend, Frankfurt 20 Nov. 2013].

A power management system is known for example from DE 10 2008 043 914 A1 “System mit zwei Hausgeräten und Verfahren zum Energiemanagement eines derartigen Systems” [System comprising two domestic appliances and method for power management in such a system] and from DE 10 2010 048 469 A1 “Energiemanagement-System, Verfahren zum Verteilen von Energie in einem Energiemanagement-System, Endgerät für ein Energiemanagement-System und Zentralgerät für ein Energiemanagement-System” [Power management system, method for distributing power in a power management system, terminal for a power management system and central unit for a power management system]. In these power management systems, the instantaneous power demand is considered and the distribution is deduced therefrom.

Another example is known from DE 11 2010 003 338 T5 “Dezentrale Lastverteilung zum Verringern der Energie-und/oder Kühlkosten in einem ereignisgesteuerten System” [Decentralised load distribution for reducing the power costs and/or cooling costs in an event-controlled system].

In addition, a system for load transfer by means of “intelligent domestic appliances” for the end-customer sectors is described in Allerding, F.; Becker, B.; Schmeck, H.: Integration intelligenter Steuerungskomponenten in reale smart-home-Umgebungen [Integration of intelligent control components in real smart-home environments]; in: Fähnrich, K.-P.; Franczyk, B. (eds.): Informatik 2010 Service Science—Neue Perspektiven fur die Informatik [New perspectives on informatics], from the series Lecture Notes in Informatics, edition P-175, pages 455-460; Bonn 2010, and Allerding, F.: Organic Smart Home—Energiemanagement für intelligente Gebäude [Organic Smart Home—power management for intelligent buildings]; Diss, Karlsruhe 2014. Here, operation using domestic appliances equipped with a corresponding control logic is flexibly controlled within a time frame predetermined by the household residents depending on the (time-variable) electricity price or on the availability of decentralised generation capacity.

Furthermore, a system for incentive-based load manipulation by means of electricity price signals in the domestic sector is set out in Pilhar, R.; Morovic, T.; Möhring-Hüser, W.: Kostenorientierte Strompreisbildung—Entwicklung und Test eines lastabhängigen Echtzeit-Tarifs in Eckernförde [Cost-oriented electricity pricing determination and development, and testing of a load-depending real-time tariff in Eckernförde]; Forschungsgesellschaft für umweltschonende Energieumwandlung und-nutzung mbH [Research association for environmentally friendly power conversion and use mbH], Kiel 1997 and Duscha, M. et al.: Modellstadt Mannheim—Evaluation der Feldtests und Simulationen, Endbericht [Smart City Mannheim—evaluation of the field tests and simulations, final report], Heidelberg 2013; available at http://www.ifeu.de/energie/pdf/moma_oeffentlicher%20EvaluationsEndbericht_V10 finale_Version.pdf and Kieβling, A. et al.: Modellstadt Mannheim (moma)—Abschlussbericht [Smart City Mannheim (moma)—concluding report], Mannheim 2013; available at http://www.ifeu.de/energie/pdf/moma_Abschlussbericht_ak_V10_1_public.pdf.

This method includes the visual display of a time-variable electricity price for domestic customers using display screens. Here, individual tariff levels or clusters of adjacent tariff levels are displayed in different colours to give the household resident a quick overview of the current price level. Generally, the coloured displays indicate three different price levels (high, medium and low). These solutions are directed towards households that do not have any domestic appliances comprising a control logic and thus have to carry out the load transfer manually. All the approaches set out in this section relate to load manipulation in separate residential units which are all separately connected to the mains power network, and do not relate to an entire urban district having its own distribution grid. In addition, the variable mains supply price for electricity from the mains network is used as the basis for control, and therefore a mixed price composed of self-generation and external supply is not used.

A power management system is also known from DE 10 2012 205 192 A1 “Energiemanagement System zur Energiebedarfsermittlung” [Power management system for determining power demand]. In this document, topological/spatial information is analysed to determine the power demand. A system for predicting electrical demand is known from DE 10 2010 027 726 A1 “Verfahren zur Bereitstellung von elektrischer Energie” [Method for providing electrical power]. This system involves predicting the power demand of motor vehicles on the basis of historical data/driving profiles.

A method for distributing power on a power supply network is known from DE 1 9 853 347 A1 “Verfahren zum Verteilen von Energie auf einem Stromversorgungsnetz” [Method for distributing power on a power supply network]. In this example, the power demand is assessed on the basis of statements made by consumers themselves on their desired electricity supply.

Decentralised generation is described on the German Wikipedia page http://de.wikipedia.org/w/index.php?title=Dezentrale_Stromerzeugung&oldid=131447941.

Solution

The present invention provides a power management method for a residential complex comprising one or more residential units or for an urban district, comprising a shared connection via which self-supplied electricity from a time-variable generation capacity is supplied to the mains power network from a decentralised self-supplied-electricity generation apparatus, and via which mains electricity is supplied to the residential complex or the urban district from the mains power network, according to claim 1, and a corresponding power management device according to claim 20.

Preferred developments are found in the respective dependent claims.

The invention described herein solves the problem of lowering electricity costs for housing estates without reducing convenience for the user. This takes place by a power management system determining suitable data and communicating said data to the residents, such that it allows them to plan electrical loads to preferably fall within times having low electricity prices. A prerequisite for this is precisely timed and sufficiently fine-tuned recording of the curves both for the decentralised generation and the loads of the individual residential units. The data are selected and communicatively prepared such that the residents of the estate are given incentives to plan their loads in a flexible manner and to reduce electricity costs in this way. Such incentives are e.g. individual savings, a reduction in the CO₂ emissions caused by their individual electricity consumption, and a comparison of the individual consumption data with comparative data. By contrast with a control system, in addition to billing for the electrical supply to the individual residential units, the focus here is on providing the residents with information as an incentive. The system informs the residents of the economic and ecological consequences of their load behaviours and thus makes an important contribution to incentive-based load manipulation of domestic customers by being instrumental in identifying the potential for load transfer and making savings. However, the residents of the residential unit in question remain the decision-makers.

The inventors have found that a reduction in electricity costs of this kind by load transfer is more effective the greater the difference between the high and low electricity costs. Here, low electricity costs usually occur when the proportion of the electrical supply coming from the decentralised power generation unit is high. The inventors have also found that the electricity costs for the electrical supply coming from the decentralised power generation unit can be particularly low if the residential complex is organised in the form of a homeowners' association (HOA), since it is then possible to hold certain parts of the complex as joint property under community regulations. These parts are e.g. the decentralised power generation units, the distribution grid in the residential complex, and the power management and power billing system. In this way, it is possible for essential parts of the systems for electrical generation and distribution to be owned by the homeowners. It is therefore not necessary for these systems to be operated by a legal entity that is separate from the owners. This is advantageous if power generation and distribution for self-consumption is associated with lower costs than power generation and distribution for third parties. This is often the case in established case law and regulations.

The inventors have found that individual incentives of this type for the residents of the residential complex can be given by meter data from the residential complex as a whole being combined with individual consumption data in a suitable manner. The manner in which this data is combined is explained in the following. The inventors have also found that, by means of such a combination of meter data from the residential complex as whole with individual consumption data, individual consumption bills for the residents of the residential complex can be generated without individual load profiles for the residents needing to be stored. This is advantageous in terms of the requirements relating to data protection.

In particular, the invention takes into account the case in which the residential complex as a whole, and not each individual residential unit, is connected to the decentralised power generation unit and to the mains power network. The relevant load transfer potential of each individual residential unit thus does not result solely from the individual consumption behaviour of the relevant residents, but also from the consumption behaviour of the entire residential complex. The system is also capable of accordingly taking into account variable supply prices from the mains network, whether these are time-variable kilowatt-hour rates or demand-dependent rates.

In a particular instance, the power management system calculates predictions of the future electrical demand on the basis of historical information, and on this basis provides the residents with information which they may use for planning the times of their power consumption.

Determining and visually displaying future electricity costs allows the residents to optimise their power consumption times. In addition to the expected electricity costs, the power management system provides additional information in order to incentivise load transfer. Additional information of this type relates to the expected CO₂ emissions according to the time-variable mixing ratio of electricity supplied in a decentralised and centralised manner, for example. The information for example also relates to parameters which are determined from the comparison of individual consumption data for the residents of an individual residential unit with suitable reference data for the entire residential complex.

A parameter of this type is for example the display of the individual power costs for a certain time period for a residential unit in comparison with the average value for a residential unit based on the entire residential complex. Suitable time periods are a day, week, month or year, for example. Suitable indicators also relate to the electricity costs per square meter or the electricity costs per resident in the residential complex.

Another suitable indicator is, for example, that the electricity consumption of a certain group of domestic appliances, e.g. refrigerator or tumble dryer, is displayed in comparison with the average electricity consumption of all the refrigerators or tumble dryers in the residential complex.

Using this comparative display, the residents can assess their consumption behaviour in relation to that of the entire residential complex, and therefore can identify possible approaches to optimisation.

In addition to determining the prediction of indicators, the power management system also visually displays said indicators. A display in the form of a traffic light having three possible display colours, red, yellow and green, is a particularly simple and intuitive approach to the visual display. The power management system switches this display to green when the current electricity costs and the expected electricity costs are lower than a threshold value to be set in advance. If this threshold value is significantly exceeded, the display is turned red to indicate particularly high electricity costs. In all other cases, the display is yellow.

The power management system determines the electricity costs for each residential unit of the residential complex in question on the basis of their individual electricity consumption. For each supply time unit (for example a quarter of an hour), the system determines the electricity costs according to the expected mixed ratio of the proportion of the electrical demand that is generated in a decentralised manner and the proportion that is supplied by the mains network. This mixed tariff results from the ratio of the electricity that is self-generated in a decentralised manner and the mains supply making up the total demand in accordance with the following formula:

mixed tariff=[(E1×T1)+(E2×T2)]/(E1+E2), (1000)

where
E1 is the number of kilowatt hours generated by the decentralised power generation unit and consumed by the residential complex in the supply time period, i.e. the self-supplied-electricity consumption of the residential complex,
T1 is the cost to be set therefor per kilowatt hour,
E2 is the number of kilowatt hours supplied to the residential complex from the mains in the supply time period, and
T2 is the cost to be set therefor per kilowatt hour.

This mixed tariff (1000) is displayed to the residents of the residential complex by the power management system as a current value and for the future as a prediction that is updated on a rolling basis.

One bill for each residential unit n on the basis of the stored load profiles and the relevant mixed tariffs at the time of use is possible in principle. This gives the residents of the individual residential units an overview of their load behaviour and makes it possible to identify the potential for load transfer and also for making savings. If someone does not want detailed information for billing purposes to be stored for reasons of data protection, the power management system according to the invention is capable of generating and using aggregated load curves for the billing and display to the customers. For this purpose, the number of kilowatt hours consumed in a billing period (for example a year) by the residential unit n from the mains are added up. In the same way, the number of kilowatt hours consumed in this period by the residential unit n from the decentralised (self-sufficient) power generation unit are added up. The billing prices are then calculated by multiplying the consumed kilowatt hours by the tariff applicable in each case in accordance with the following formula:

billing price (n)=E1_{ges}ⁿ×T1+E2_{ges}ⁿ×T2. (1001)

where
E1_{ges}ⁿ is the number of kilowatt hours supplied to the residential unit n from the photovoltaic system in the billing period,
T1 is the costs to be set therefor per kilowatt hour,
E2_{ges}ⁿ is the number of kilowatt hours supplied to the residential unit n from the mains in the billing period,
T2 is the cost to be set therefor per kilowatt hour.

In the embodiment, it is demonstrated by way of example how E1_{ges}ⁿ and E2_{ges}ⁿ can be determined from meter data.

It is clear from formula (1001) that only aggregated consumption data, and no individual load profile data, are used here. This approach is therefore highly compatible with any possible data-protection concerns.

To motivate advantageous load transfer behaviour, with the use of individual load profiles and summed load profiles, the residents are informed of the implications of their load behaviour (as a whole) by the electricity costs, which are based on the mixed ratio of self-generation and external supply from the mains power network. In addition, the load behaviour is analysed in relation to the environmental impact and sustainability. For this purpose, the power management system according to the invention determines CO₂ emission values. In the process, it sets the CO₂ value for power from the photovoltaic system to 0 g/kWh and for power from the mains to the values specified by the supplier. The CO₂ emission values are displayed in a similar manner to the power consumption data. For the billing period, the following results in accordance with the following formula:

CO₂ emission value=E2_{ges}^{n×CO}₂^{mains}, (1002)

where
E2_{ges}ⁿ is the number of kilowatt hours supplied to the residential unit n from the mains in the billing period,
CO₂^{mains} is the amount of CO₂ emissions in g/kWh specified by the energy supplier.

Similarly, the CO₂ emission values can also be determined for different periods, by the number of kilowatt hours supplied to the residential unit n from the mains in this other period being used instead of E2_{ges}ⁿ.

### BRIEF DESCRIPTION OF THE DRAWINGS

In the drawings:

FIG. 1 shows a typical residential complex;

FIG. 2 is a diagram of how the self-supply level is determined from data from the residential complex;

FIG. 3 is a diagram of how the number of kilowatt hours consumed in total by the residential unit n in the billing period from the photovoltaic system is determined from the “number of kilowatt hours consumed by the residential unit n in m quarter hours from the photovoltaic system”, and the same for the mains electricity;

FIG. 4 shows a method outlined as an embodiment of the invention in the form of a flow diagram; and

FIG. 5 shows an embodiment of a computer in the form of a block diagram.

### EMBODIMENTS

Embodiments of the invention will be described in the following. Reference will be made to the drawings.

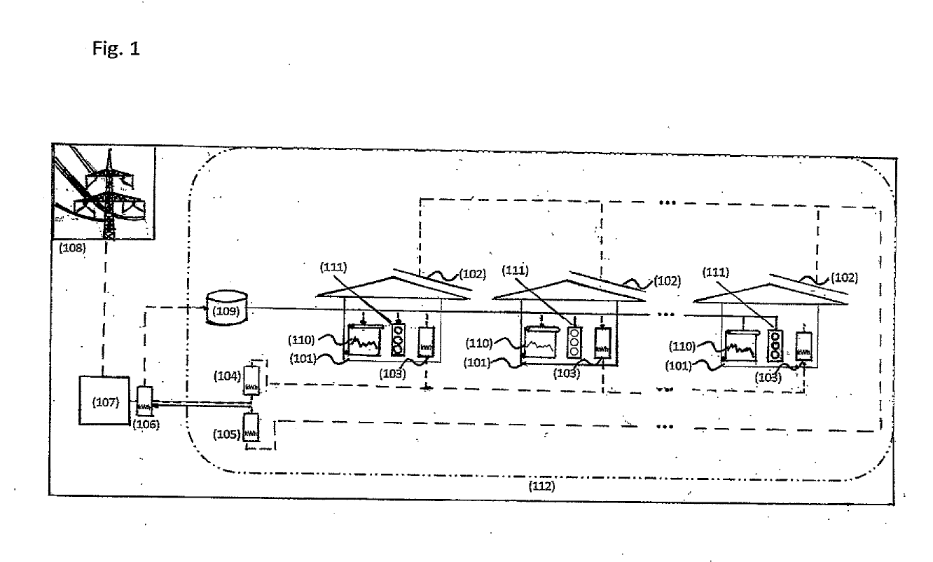

FIG. 1 shows a typical residential complex. There are one or more residential units (101) in the residential complex (112). The residential units are located in one or more houses. One or more of the houses are equipped with a photovoltaic system (102). In the following, the embodiment is explained for the specific case in which the decentralised power generation unit is a photovoltaic system. However, the invention is generally also applicable to other decentralised power generation units, for example cogeneration systems.

In each residential unit, the electrical loads are connected to electricity meters (103). These meters (103) measure the total electricity consumption of the residential unit. There is a separate electricity meter (103) for each residential unit within a house. The total photocurrent generated is determined by a generation meter (105). In this embodiment, the electricity consumed by all the houses is determined by a supply meter (104).

It is noted, however, that a supply meter (104) of this type is not strictly necessary, and the total electricity consumption can be calculated by adding together the consumption from separate meters. For the rest of the explanation of the embodiment, it is however assumed that there is a supply meter (104).

The flows of electricity from the supply meter (104) and the generation meter (105) are added together, and the resulting electricity total is measured by a summation meter (106). The summation meter (106) is a bidirectional meter that measures both the flow of power from the mains into the residential complex and the flow of power from the residential complex into the mains. The information from the meters (104) and (106) is used to determine the mixed tariff (1001) and the PV self-supply level (204).

The mixed tariff (1001) is determined and displayed by the power management system. This is demonstrated by the following example: the tariff for mains supply is T2=0.20 C= per kilowatt hour. The tariff for electricity from the photovoltaic system is T1=0.10 C= per kilowatt hour. In a supply quarter hour (201), E2=100 kWh (202) is supplied to the residential complex from the mains (meter (106)) and E1=200 kWh (203) photocurrent generated by the photovoltaic system is consumed in the residential complex. The power E1 generated by the photovoltaic system and consumed in the residential complex is, for example, determined as the difference between the total power consumed by the residential complex (meter (104)) and the power supplied to the residential complex from the mains (meter (106)). The mixed tariff is then produced by the weighted addition in accordance with formula (1001) [(E1×T1)+(E2×T2)]/(E1+E2). The mixed tariff in the example is therefore 0.13 C=/kWh.

Furthermore, a photovoltaic self-supply level is determined and displayed by the power management system. The self-supply level is calculated in accordance with the following formula:

self-supply level=E1/(E1+E2) (204) (1004)

For the example numbers given, the self-supply level is 67%. The mixed price and the self-supply level are determined and displayed by the power management system.

By way of example, the billing for the individual residential unit n is determined in accordance with the following method:
1. Determining the self-supply level Sᵢ in the i-th quarter hour, where:
   E1ᵢ is the number of kilowatt hours generated by the photovoltaic system and consumed in the residential complex in the i-th quarter hour of the billing period. This is determined as the difference between the total power consumed in the residential complex (meter (104)) and the power supplied to the residential complex from the mains (meter (106)).
   E2ᵢ is the number of kilowatt hours supplied from the mains in the i-th quarter hour of the billing period. This is supplied by the meter (106).
   Sᵢ=E1ᵢ/(E1ᵢ+E2ᵢ) (204)
   The self-supply level Sᵢ is the same for all the residents of the residential complex and is determined for each i-th quarter hour (i=1 to m) in the billing period.
2. For each quarter hour in the billing period, the number of kilowatt hours from the photovoltaic system is determined for the individual residential unit n. For the i-th quarter hour, this number is referred to as E1ᵢⁿ. It is calculated according to:
   E1ᵢⁿ=Sᵢ×number of kilowatt hours measured by the individual meter number n (103) in the i-th quarter hour of the billing period
3. The number of kilowatt hours consumed in total by the residential unit n in the billing period from the photovoltaic system (301) is calculated. This number is referred to as E1_{ges}ⁿ. Said number is calculated by summation/addition of the numbers E1ᵢⁿ of kilowatt hours in the supply quarter hour from the photovoltaic system (205) over all (i=1 to m) the quarter hours in the billing period, according to
   E1_{ges}ⁿ=Σᵢ₌₁^{m}E1ᵢⁿ
4. For each quarter hour in the billing period, the number of kilowatt hours from the mains is determined for the individual residential unit n. For the i-th quarter hour, this number is referred to as E2ᵢⁿ. It is calculated according to:
   E2ᵢⁿ=(1−Sᵢ)×number of kilowatt hours measured by the individual meter number n (103) in the i-th quarter hour of the billing period
5. The number of kilowatt hours consumed in total by the residential unit n in the billing period from the mains (302) is calculated. This number is referred to as E2_{ges}ⁿ. Said number is calculated by summation/addition of the numbers E2ᵢⁿ of kilowatt hours in the supply quarter hour from the mains (206) over all (i=1 to m) the quarter hours in the billing period, according to
   E2_{ges}ⁿ=Σᵢ₌₁^{m}E2ᵢⁿ
6. The individual billing price is determined. This is referred to as Pⁿ. Pⁿ is calculated according to
   Pⁿ=E1_{ges}ⁿ×T1+E2_{ges}ⁿ×T2, where
   T1 is the tariff in C= per kilowatt hour for photocurrent, and
   T2 is the tariff in C= per kilowatt hour for mains electricity.

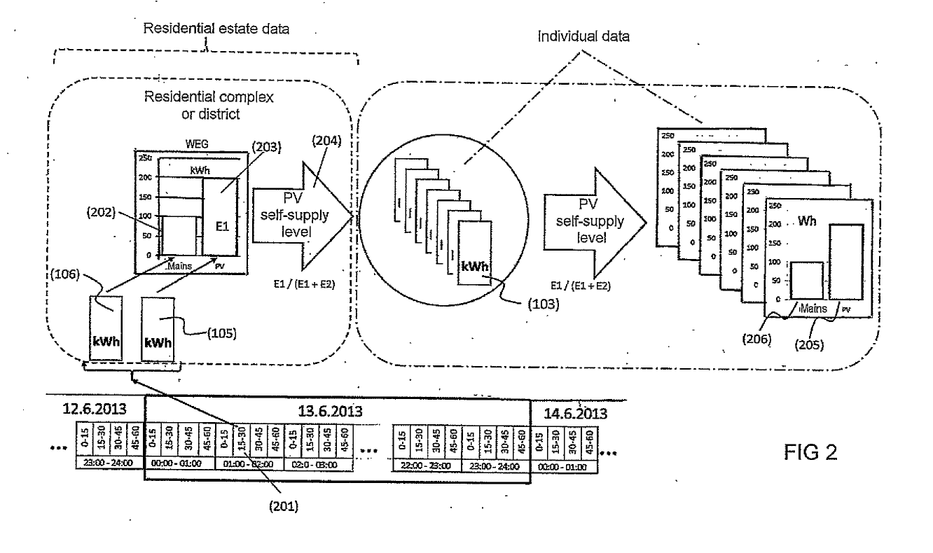

FIG. 2 shows how the self-supply level (204) is determined from data from the residential complex (202), (203), and how the “number of kilowatt hours consumed in this quarter hour by the residential unit n from the photovoltaic system” (205) and the “number of kilowatt hours consumed in this quarter hour by the residential unit n from the mains” (206) are determined from said self-supply level and the individual electricity consumption data (103). FIG. 2 outlines the method for one quarter hour (201).

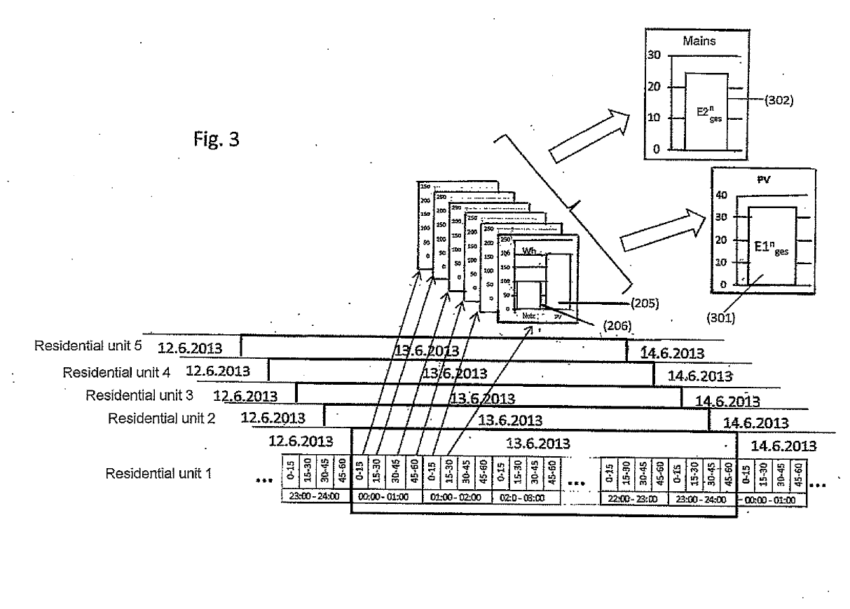

FIG. 3 shows how the number of kilowatt hours consumed in total by the residential unit n in the billing period from the photovoltaic system (301) is determined from the “number of kilowatt hours consumed by the residential unit n in m quarter hours from the photovoltaic system”, and the same for the mains electricity (302). FIG. 3 outlines the summation/addition of the quarter hours for the billing period.

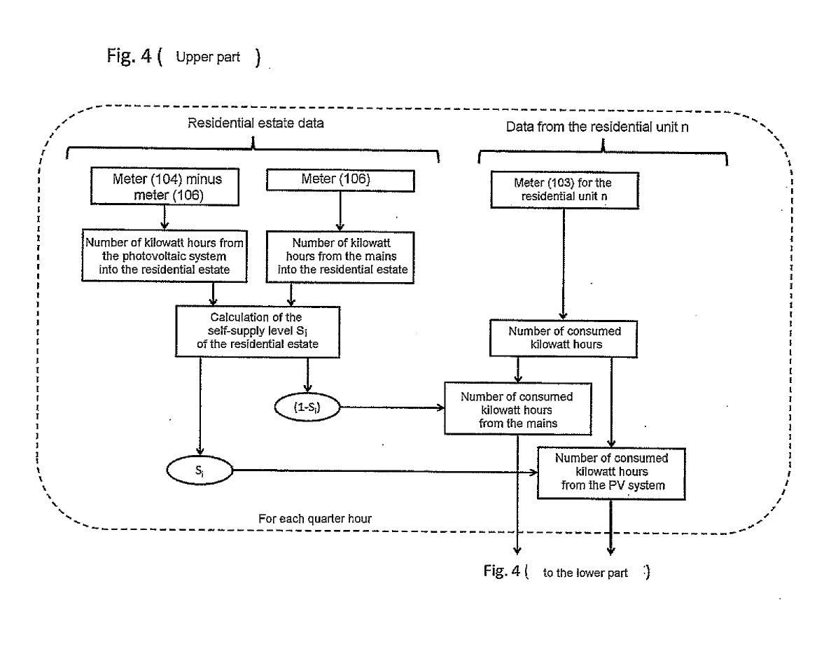

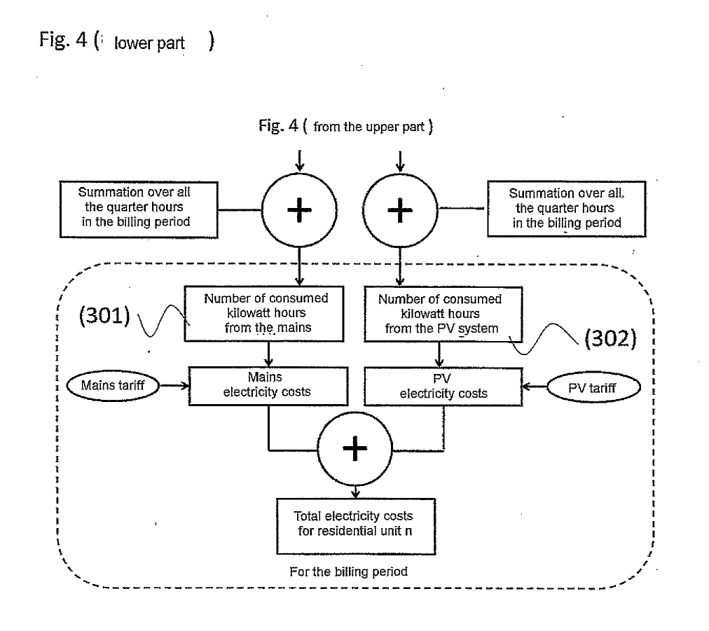

The method outlined as an embodiment of the invention is shown in FIG. 4 in the form of a flow diagram. It can be seen that the claimed determination of the individual electricity costs does not require load profile data, but just the two numbers for consumed kWh (301), (302).

In the embodiment according to FIG. 1, the residential complex is connected to the mains by a medium-voltage transformer (107). The transformer (107) is connected to the medium-voltage network (108). The information from the bidirectional meter (106) is passed to the computer of the power management system (109). Said computer calculates the current and predicted electricity prices, the indicators and other information that is important to display. This information is displayed on suitable terminals (110). Terminals of this type may be PCs, tablet computers or mobile telephones, for example. There are traffic-light displays (111) in the residential units. The traffic-light displays visually display the cost situation for electricity using a red, green or yellow signal. A green signal is emitted if the self-supply level is above a threshold. For example, green is displayed in the i-th quarter hour when Sᵢ=1, red is displayed when Sᵢ<0.2 and yellow is displayed for all other values of Sᵢ. For example, a flashing red signal is displayed when the mains supply rises above 70% of the annual high up to the present and there is the risk of the mains demand rate being increased.

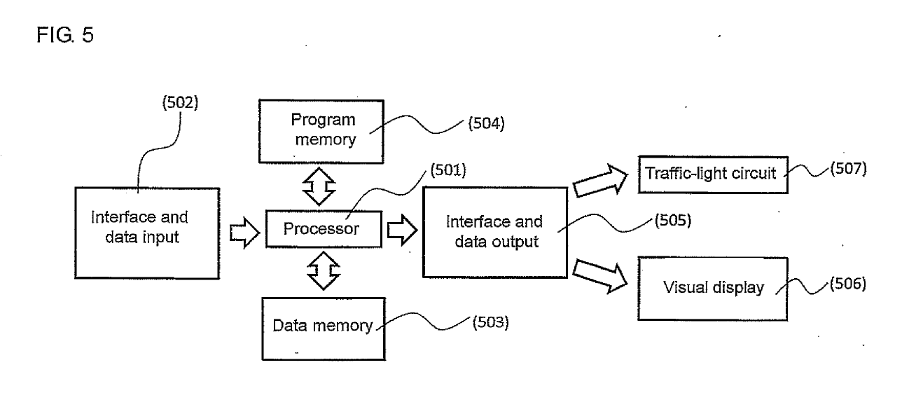

FIG. 5 shows an embodiment of a computer (403) in the form of a block diagram.

Said computer comprises a processor (501). The processor (501) executes program instructions for example, which are stored in the program memory (504), and stores e.g. intermediate results or the like in the data memory (503). The program memory (504) and/or the main memory (503) can be used by the processor (501) to store data, such as meter data or tariff data. Program instructions which are stored in the program memory (504) relate in particular to determining at least the stated electricity costs.

The program instructions may for example be included in a computer program, which is stored in the program memory (504) or has been loaded into the program memory (504), for example of a computer program product, in particular a computer-readable storage medium, or via a network.

The processor (501) obtains data via the interface and data input (502). The data are, for example, meter data or tariff data. The processor (501) generates new data and outputs these data via the interface and data output (505). The output data are visually displayed (507) and/or passed to a traffic-light circuit (506).

1. Power management method for a residential complex comprising one or more residential units or for an urban district,
comprising a shared connection via which self-supplied electricity from a time-variable generation capacity is supplied to the mains power network from a decentralised self-supplied-electricity generation apparatus, and via which mains electricity is supplied to the residential complex or the urban district from the mains power network,
wherein the demand not covered by the decentralised self-supplied-electricity generation apparatus is determined according to the mains supply level 1−S of the electricity and the demand covered by the decentralised self-supplied-electricity generation apparatus is determined according to the self-supply level S of the electricity for the residential complex or urban district,
wherein time dependency of the electricity consumption of a residential unit is recorded,
wherein electricity costs for the residential unit of the residential complex or of the urban district are determined by taking into account the determined time dependency of the mains supply level and the self-supply level, the recorded time dependency of the electricity consumption of the residential unit, and the relevant tariffs for mains electricity and self-supplied electricity.

2. Power management method according to claim 1, characterised in that a current mixed tariff is determined from the determined time dependency of the mains supply level and self-supply level and from the relevant tariffs for mains electricity and self-supplied electricity.

3. Power management method according to claim 2, characterised in that future mixed tariffs are extrapolated from previously determined mixed tariffs, and are displayed.

4. Power management method according to claim 1, characterised in that the individual electricity costs for a residential unit of the residential complex or of the urban district are determined by the billing period being divided into time intervals and the individual electricity consumption for each time interval in kWh and the specific variable electricity costs of the residential complex or urban district for the same time interval in C=/kWh are multiplied, and the C= figures thus determined for all time intervals are added together.

5. Power management method according to claim 1, characterised in that the individual electricity costs of the residential unit are determined by the determination time period being divided into time intervals and
a. in each time interval, the mains supply level 1−S and the self-supply level S is determined for this time interval, and
b. the individual electricity consumption SV of the residential unit is determined in the same time interval and, from this, the proportion SV×S is added to the self-supplied-electricity consumption and the proportion (1−S)×SV is added to the mains electricity consumption, and
c. the individual self-supplied electricity costs are determined in the billing period by the stored total for the self-supplied electricity consumption being multiplied by the tariff for self-supplied electricity, and
d. the individual mains electricity costs are determined in the billing period by the stored total for the mains electricity consumption being multiplied by the tariff for mains electricity, and
e. the individual total electricity costs are determined as a sum of individual self-supplied electricity costs and individual mains electricity costs.

6. Power management method according to claim 5, characterised in that historical individual electricity costs are displayed over time.

7. Power management method according to claim 5, characterised in that expected future individual electricity costs are extrapolated and displayed over time.

8. Power management method according to claim 1 using a traffic-light display in red, yellow or green, characterised in that the traffic-light display visually displays the electricity-cost situation, wherein
a. red shows when the self-supply level is lower than a predefined lower threshold and
b. green shows when the self-supply level is higher than a predefined upper threshold.

9. Power management method according to claim 1 using a traffic-light display in red, yellow or green, characterised in that the traffic-light display visually displays the electricity-cost situation, for example flashing red shows when the mains supply level or the electrical supply of the residential complex or the urban district averaged over a predetermined time interval is greater than a predefined percentage of the annual high up to the present.

10. Power management method according to claim 1, characterised in that the residential units of the residential complex or urban district are informed of individual electricity costs for a time period or a plurality of time periods.

11. Power management method according to claim 1, characterised in that the residential units of the residential complex or urban district are informed of individual electricity consumption values in comparison with average electricity consumption values of the residential complex or urban district.

12. Power management method according to claim 11, characterised in that the electricity consumption values are based on the living area of the residential unit.

13. Power management method according to claim 11, characterised in that the electricity consumption values are based on the refrigerator, freezer, washing machine or tumble dryer.

14. Power management method according to claim 1, characterised in that the residential units of the residential complex or urban district are informed of individual electricity consumption values in comparison with electricity consumption values of other residents in the residential complex or urban district.

15. Power management method according to claim 1, characterised in that the residential units of the residential complex or urban district are informed of the level of CO₂ emissions corresponding to their individual electricity consumption value.

16. Power management method according to claim 3, characterised in that the future data is determined and displayed for 24 hours over the course of a day.

17. Power management method according to claim 1, characterised in that the decentralised self-supplied-electricity generation apparatus is a photovoltaic system.

18. Power management method according to claim 1, characterised in that the decentralised self-supplied-electricity generation apparatus is a cogeneration system.

19. A computer program to be executed by a computer processor comprising program instructions, wherein the program instructions prompt a processor (501) to carry out the method according to claim 1 when the computer program is executed by the computer processor.

20. Power management method for a residential complex comprising one or more residential units or for an urban district, comprising:
a shared connection via which self-supplied electricity from a time-variable generation capacity is supplied to the mains power network from a decentralised self-supplied-electricity generation apparatus, and via which mains electricity is supplied to the residential complex or the urban district from the mains power network,
wherein the shared connection to the decentralised self-supplied-electricity generation apparatus and the shared connection to the mains power network are connected to a bidirectional meter, which supplies an information signal from which the demand not covered by the decentralised self-supplied-electricity generation apparatus can be continuously determined according to the mains supply level 1−S of the electricity and the demand covered by the decentralised self-supplied-electricity generation apparatus can be continuously determined according to the self-supply level S of the electricity for the residential complex or urban district, and
an apparatus for recording time dependency of the electricity consumption of a residential unit,
wherein a determination apparatus is provided which is designed such that it determines electricity costs for the residential unit of the residential complex or of the urban district by taking into account the determined time dependency of the mains supply level and the self-supply level, the recorded time dependency of the electricity consumption of the residential unit, and the relevant tariffs for mains electricity and self-supplied electricity.
